(19) United States
(12) Patent Application Publication
(10) Pub. No.: US 2006/0185832 A1
(43) Pub. Date: Aug. 24, 2006

(54) Heat radiation module with transverse flow fan

(75) Inventors: Chen-Jung Chuang, Taipei (TW); Ching-Min Yang, Taipei (TW); Chun-Liang Ho, Taipei (TW)

Correspondence Address: G. LINK Co., LTD, 3550 Bell Road, MINOOKA, IL, 60447, US

(73) Assignee: ASIA VITAL COMPONENT CO., LTD.

(21) Appl. No.: 11/062,790

(22) Filed: Feb. 23, 2005

(51) Int. Cl. H01L 23/467

(52) U.S. Cl. 165/121

(57) ABSTRACT

A heat radiation module with a transverse flow fan includes a radiator and a transverse flow fan. The radiator provides cooling fins and the transverse flow fan is attached to a lateral side of the radiator. The transverse flow fan further includes a rotor device and a stator device. The rotor device provides a fan blade set and a hub part and the fan blade set is radially attached to the circumference of the hub part to form a centrifugal fan. The stator device is rotationally joined to the rotor device. The air current induced by the rotor device is guided to pass through the radiator.

### BACKGROUND OF THE INVENTION

1. Field of the Invention

The present invention is related to a heat radiation module with transverse flow fan and particularly to a heat radiation module provided with a radiator and a transverse flow fan.

2. Brief Description of the Related Art

Referring to FIGS. 1 and 2, a conventional heat radiation module includes an axial flow fan 11 and a radiator 12. The axial flow fan 11 is composed of a stator device 111, a rotor device 112 and a fan frame 113. The rotor device 112 further s composed of a hub part 112a, a fan blade set 112b circumferentially attached to the hub part 112a and a magnetic component 112c. The stator device 111 further includes a silicone steel sheet 111a, a coil 111b, a bearing seat 111c and an insulation frame 111d. The stator device 111 is received in the fan frame 113 and rotationally joined to the rotor device 112. The radiator 12 further includes a plurality of cooling fins 121 and a plurality of heat removing paths 122 between the cooling fins 121.

After the axial flow fan 11 of the conventional heat radiation module is assembled and fixedly attached to the radiator 12, the hub part 112a with the fan blade set 112b is driven to rotate by means of the stator device 111 and the rotor device 112 performing phase changing rotation. Air current induced by the rotational fan blade set is guided with the heat removing paths 122 before passing through the radiator 12 such that heat in the radiator is dissipated with the air current.

However, the conventional heat radiation module has the following deficiencies:

(1) The air current induced by the rotating fan blade set often centers at lower part of the fan blade set and a dead corner of heat dissipation is formed at the lower part of the hub part 112a. Usually, a heat dissipated object such as the central processing unit (CPU) on the circuit board 131 of a computer is attached to the center of the radiator such that the central area of the radiator 12 occurs highest temperature and is the spot most required to dissipate heat. But, the conventional heat radiation module is incapable of cooling the central area of the radiator 12. Thus, the overall effect of heat dissipation of the conventional heat radiation module is unfavorably low.

(2) The air current induced by the rotating fan blade set being guided out via two lateral sides of the radiator 12 and the flow rate moving out from each lateral side is different from each other such that heat dissipation effects at the two lateral sides are inconsistent and the heat conductive effect of the radiator 12 is incapable of enhancing completely.

### SUMMARY OF THE INVENTION

An object of the present invention is to provide a heat radiation module with transverse flow fan with which heat dissipation effect can be promoted effectively.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a sectional view of the conventional heat radiation module;

FIG. 2 is a top view of the conventional heat radiation module;

FIG. 3 is a top with partial sectional view of the first preferred embodiment of a heat radiation module with transverse flow fan according to the present invention;

FIG. 4 is a perspective view of the first embodiment of a heat radiation module with transverse flow fan according to the present invention;

FIG. 5 is a top with partial sectional view of the second preferred embodiment of a heat radiation module with transverse flow fan according to the present invention;

FIG. 6 is a perspective view of the second embodiment of a heat radiation module with transverse flow fan according to the present invention;

FIG. 7 is a top with partial sectional view of the third preferred embodiment of a heat radiation module with transverse flow fan according to the present invention;

FIG. 8 is a top with partial sectional view of the fourth embodiment of a heat radiation module with transverse flow fan according to the present invention;

FIG. 9 is a top with partial sectional view of the fifth preferred embodiment of a heat radiation module with transverse flow fan according to the present invention;

FIG. 10 is a perspective view of the fifth preferred embodiment of a heat radiation module with transverse flow fan according to the present invention;

FIG. 11 is a top with partial sectional view of the sixth preferred embodiment of a heat radiation module with transverse flow fan according to the present invention; and

FIG. 12 is a side sectional view of the sixth preferred embodiment of a heat radiation module with transverse flow fan according to the present invention.

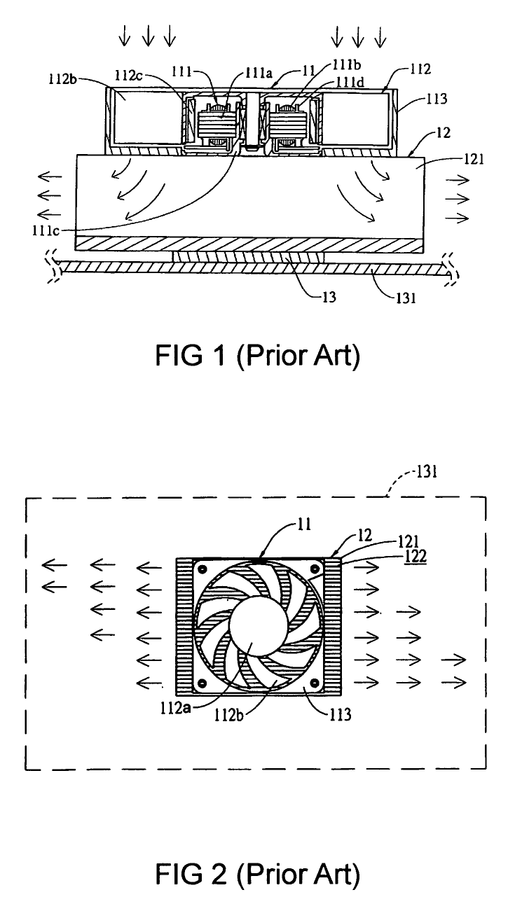

### DETAILED DESCRIPTION OF THE INVENTION

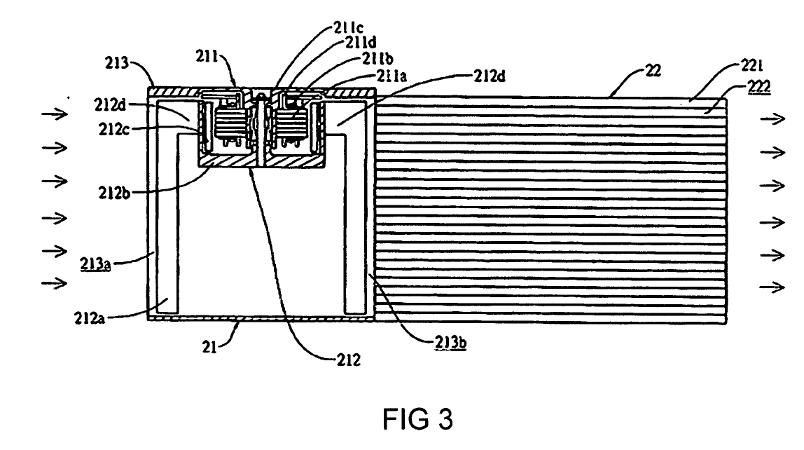

Referring to FIG. 3, the first embodiment of a heat radiation module with transverse flow fan according to the present invention comprises a transverse flow fan 21 and a radiator 22. The transverse flow fan 21 further includes a stator device 211 and a rotor device 212. The rotor device 212 further includes a fan blade set 212a, a hub part 212b and a magnetic component 212c. The fan blade set 212a is radially arranged at the circumference of the hub part 2122b to form a centrifugal fan. The hub part 212b is rotationally joined to the stator device 211. The stator device 211 further includes an electrode plate 211a such as a silicone steel sheet, a coil 211b, a base 211c and an insulation frame 211d. The radiator 22 includes a plurality of cooling fins 221 and a plurality of heat removing paths 222. The transverse flow fan 21 is attached to a side of the radiator 22 to guide air current generated by the rotor device 212 through the radiator 22.

When the heat radiation module of the present invention is set up, the stator device 211 is mounted in the fan frame 213 being rotationally joined to the hub part 212b and the support part 212d is disposed between and joined to the hub part 212b and the fan blade set 212a. Finally, the transverse flow fan 21 is attached to a side of the radiator 22.

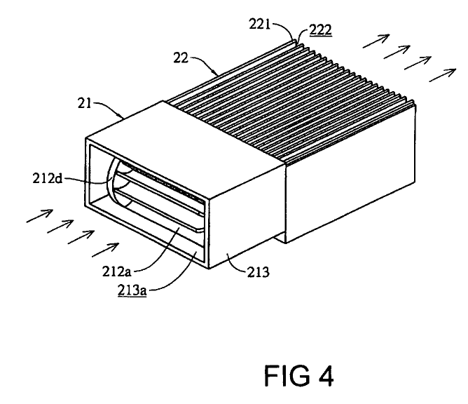

Referring to FIG. 4, the fan frame 213 provides an inlet 213a and an outlet 213b at both lateral sides thereof respectively such that the air current induced by the rotor device 212 enters via the inlet 213a and leaving via the outlet 313b.

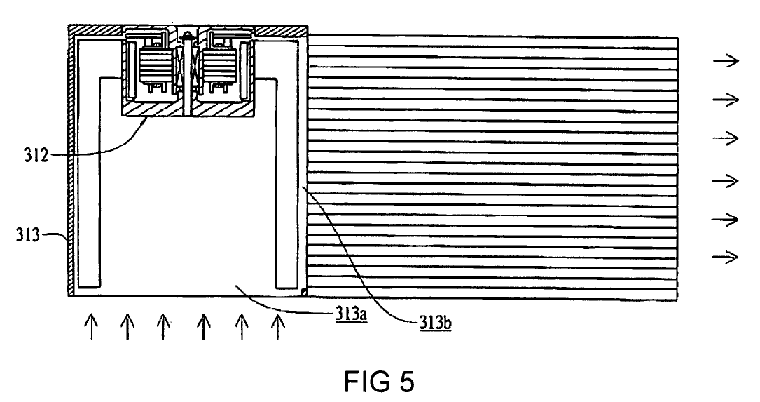

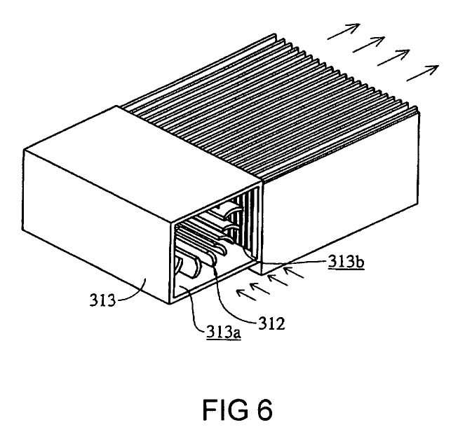

Referring to FIGS. 5 and 6, the second embodiment of a heat radiation module with transverse flow fan according to the present invention is illustrated. The characteristics of the second embodiment of the present invention is in that the inlet 313a is disposed at a side of the fan frame 313 and the outlet 313b is disposed at another side next to the inlet 313a such that the air current induced by the rotor device 312 enters via the inlet 313a and turns 90° before leaving via the outlet 313b.

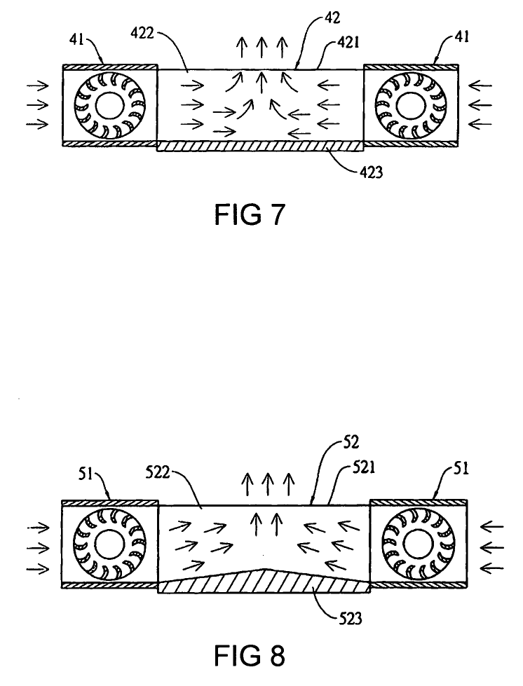

Referring to FIG. 7, the third embodiment of a heat radiator module with transverse flow fan according to the present invention is illustrated. The characteristics of the third embodiment of the present invention is in that the radiator 42 includes a plurality of cooling fins 421 and a plurality of heat removing paths 422 between the cooling fins 421. The cooling fins 421 are mounted to a square base 423 and both lateral sides of the radiator 42 is provided with a transverse flow fan 41 respectively. Air current induced by the respective transverse flow fan 41 can be guided to the central area of the radiator 42 via the heat removing paths 422 and discharged upward due to air pressure at the upper part of the radiator 42 being less than that at the heat removing paths 422.

Referring to FIG. 8, the fourth embodiment of a heat radiator module with transverse flow fan according to the present invention is illustrated. The characteristics of the fourth embodiment of the present invention is in that the radiator 52 includes a plurality of cooling fins 521 and a plurality of heat removing paths 522 between the cooling fins 521. The cooling fins 521 are mounted to the base 523, which protrudes from the center of the radiator 52 and both lateral sides of the radiator 52 is attached with a transverse flow fan 51 respectively. The air current induced by the respective transverse flow fan 51 is guided to the central area of the radiator 52 via the heat removing paths 522 and discharged upward due to the base 523 of the radiator 52 protruding from the center thereof.

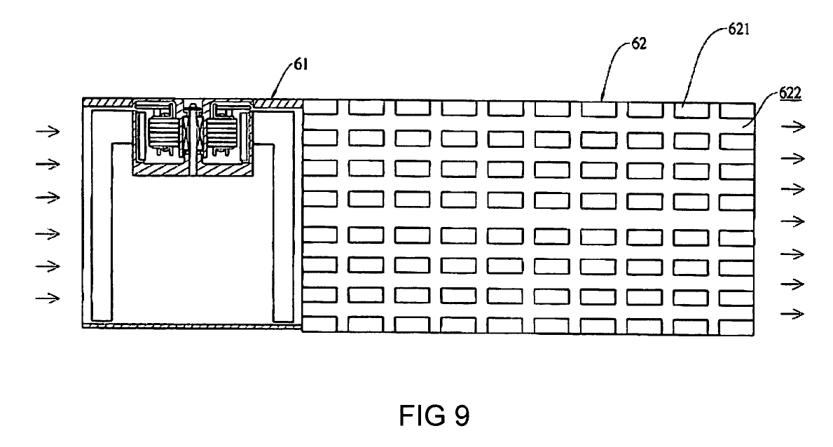

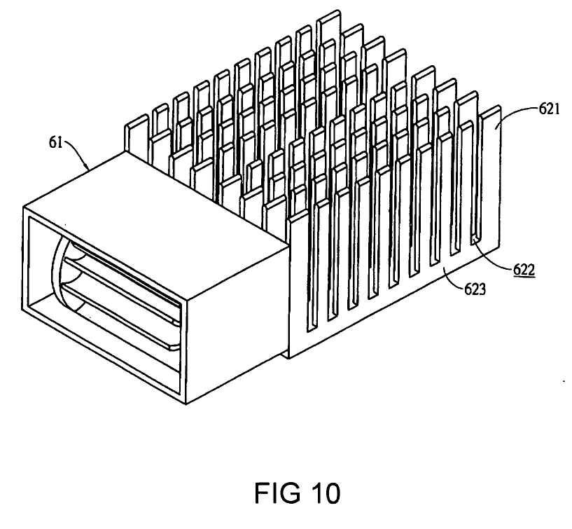

Referring to FIGS. 9 and 10, the fifth embodiment of a heat radiator module with transverse flow fan according to the present invention is illustrated. The characteristics of the fifth embodiment of the present invention is in that the radiator 62 is a cylindrical radiator and includes a plurality of cooling fins 621 and a plurality of heat removing paths 622 between the cooling fins 621. The cooling fins 521 are mounted to the base 623 and a lateral side of the radiator 62 is attached with a transverse flow fan 61. The air current induced by the transverse flow fan 61 is guided to pass through the radiator 62 via the heat removing paths 622 and carry the heat generated by the radiator 62 outward rapidly.

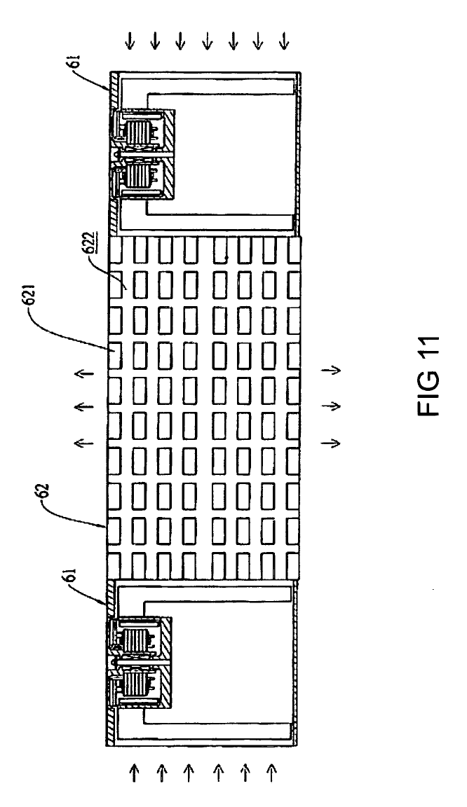

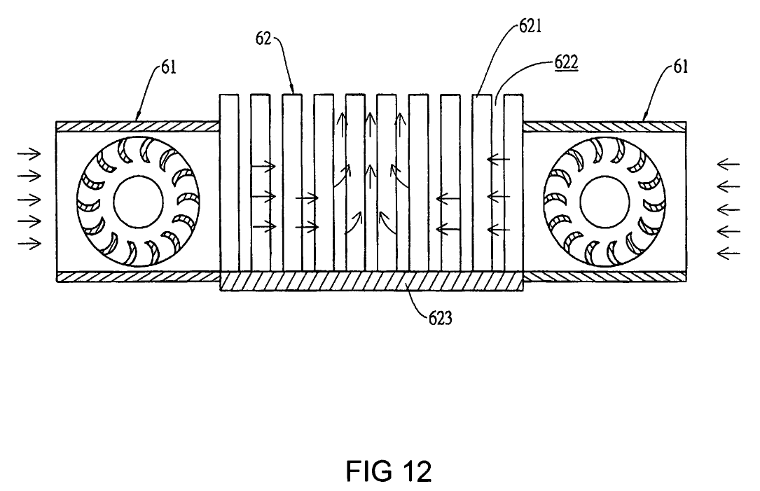

Referring to FIGS. 11 and 12, the sixth embodiment of a heat radiator module with transverse flow fan according to the present invention is illustrated. The characteristics of the sixth embodiment of the present invention is in that both lateral sides of the radiator 62 are attached with a transverse flow fan 61 respectively. The air current induced by the respective transverse flow fan 61 is guided to the central area of the radiator 62 via the heat removing paths 622 and discharged outward via the center of the radiator 62 or upward due to air pressure at the upper part of the radiator 62 being less than that at the heat removing paths 622.

As the foregoing, comparing to the prior art, the heat radiation module with a transverse flow fan according to the present invention has the following advantages and effectiveness:

(1) The air current generated by the transverse flow fan (21, 41, 51, 61), which is attached to lateral sides of the radiator (22, 42, 52, 52), can reach to the entire radiator (22, 42, 52, 62) evenly so that it is capable of enhancing overall effect of heat dissipation of the radiator.

(2) The air current generated by the transverse flow fan (21, 41, 51, 61), which is attached to lateral sides of the radiator (22, 42, 52, 52), is guided out via both lateral sides of the radiator evenly so that equal amount of air moving through each of the heat removing paths (222, 422, 522, 622) can be obtained.

(3) Both lateral sides of the radiator (22, 42, 52, 62) can provides a transverse flow fan (21, 41, 51, 61) respectively so that the air at the heat removing paths (222, 422, 522, 622) can be increased so as to heat dissipation efficiency of the radiator (22, 42, 52, 52).

While the invention has been described with referencing to preferred embodiments thereof, it is to be understood that modifications or variations may be easily made without departing from the spirit of this invention, which is defined by the appended claims.

1. A heat radiation module with a transverse flow fan, comprising:
a radiator, providing a plurality of cooling fins; and
a transverse flow fan, being attached to a lateral side of the radiator;
wherein the transverse flow fan further comprises:
a fan frame, providing an inlet and an outlet at two opposite lateral sides thereof respectively;
a rotor device, providing a fan blade set, a hub part and a magnetic component and the fan blade set being radially attached to the circumference of the hub part to form a centrifugal fan; and
a stator device, being rotationally joined to the rotor device and providing an electrode plate, a coil and a base;
whereby, air current induced by the rotor device enters the transverse flow fan via the inlet and leaves the transverse flow fan via the outlet before passing through the radiator.

2. The heat radiation module with a transverse flow fan as defined in claim 1, wherein a support part is disposed between the fan blade set and hub part and being joined to both the fan blade set and the hub part.

3. The heat radiation module with a transverse flow fan as defined in claim 1, wherein the cooling fins are mounted to a square base of the radiator.

4. The heat radiation module with a transverse flow fan as defined in claim 1, wherein the cooling fins are mounted to a base protruding from the central area of the radiator.

5. The heat radiation module with a transverse flow fan as defined in claim 1, wherein the radiator is a cylindrical radiator.

6-32. (canceled)
